(19) United States
(12) Patent Application Publication
(10) Pub. No.: US 2014/0097080 A1
(43) Pub. Date: Apr. 10, 2014

(54) SPUTTERING MAGNETRON AND METHOD FOR DYNAMICALLY INFLUENCING THE MAGNETIC FIELD

(71) Applicant: VON ARDENNE ANLAGENTECHNIK GMBH, Dresden (DE)

(72) Inventors: Hans-Jurgen HEINRICH, Grossroehrsdorf (DE); Sven HAEHNE, Dresden (DE); Rolf RANK, Dresden (DE)

(73) Assignee: VON ARDENNE ANLAGENTECHNIK GMBH, Dresden (DE)

(21) Appl. No.: 14/045,184

(22) Filed: Oct. 3, 2013

(30) Foreign Application Priority Data
Oct. 4, 2012 (DE) 10 2012 109 424.1

(51) Int. Cl. C23C 14/35

(52) U.S. Cl. CPC C23C 14/35
USPC 204/192.13; 204/298.03

(57) ABSTRACT

A sputtering magnetron for coating a substrate includes a target and a magnet system that can be displaced relative to one another. The magnet system forms a magnetic field that penetrates the target, and has a support apparatus, a support plate with magnets arranged thereon, and actuators. The support apparatus is connectable to the support plate by the actuators such that distance between the magnet system and the target can be set, at least in sections. A cooling circuit cools the magnet arrangement and the target by a coolant. A layer measuring device obtains data of layer properties of at least one layer deposited on the substrate. Magnet system controls evaluate the data obtained and generate manipulated variables employed as the input variables of the actuators. A method for dynamically influencing the magnetic field is also provided.

### CROSS REFERENCE TO RELATED APPLICATION

This application claims priority of German patent application no. 10 2012 109 424.1 filed on Oct. 4, 2012, the entire contents of which is hereby incorporated by reference herein.

### BACKGROUND ART

The invention relates to a sputtering magnetron for PVD coating of substrates, in particular to a sputtering magnetron with rotating target tube, a so-called tube magnetron, and a method for dynamically influencing the magnetic field during a sputtering process.

In the case of tube magnetrons, the cathode and hence the target material arranged thereon rotate about a stationary magnet system or a moving, e.g. rotating, magnet system is moved in the interior of the target. The magnetic field generated by the magnet system forms a racetrack over the surface of the target material which extends substantially in two straight tracks along the target tube. The tube magnetron can reduce the target material yield and hence the sputtering costs.

Known magnet systems comprise a support apparatus and a support plate with magnets which are arranged thereon and configured to form a magnet arrangement. The magnet systems are installed into the target tube in a manner that conforms to plasma processes and is secured against twisting. By way of example, the magnet system can, to this end, be attached to a support apparatus, preferably a support tube, fixedly arranged in the interior of the target tube such that the magnets are arranged at a small distance from the inner surface of the target tube.

In addition to increasing the target material yield, the objects of optimizing the sputtering process include increasing the coating homogeneity and the adjustability of the coating rate.

The magnet systems, which already have a very homogeneous design and have already been measured with much effort, are, depending on the application, readjusted for starting up the sputtering process by so-called shimming, for example by attaching compensation disks between the magnet system and the support apparatus at the respective attachment sites between the two. Shimming is a discrete or continuous defined deformation of the magnet system with the magnets arranged thereon.

A disadvantage of this method is that the magnet system can only be manipulated during sputtering breaks. To this end, the sputtering installation initially needs to be ventilated and the magnet systems subsequently need to be removed at the separation planes between the target tube and its mounting apparatuses, the so-called end blocks, which serve for rotatable mounting of the target tube and the supply of torque, electricity and coolant. As a result, relatively large amounts of time are consumed by the manipulation of each magnet system and this is accompanied by an interruption of the process occurring in the coating installation, i.e. by a production down-time. Even if several magnet systems can be manipulated at the same time by more members of staff, this process may need to be repeated several times on the substrate until an optimum layer quality, e.g. in respect of the coating homogeneity, has been achieved.

The magnet system manipulated thus is optimized for a large part of the target service life. However, target material is ablated more or less continuously during the sputtering process. As a result of the above-described target material ablation, there is a continuous change in the magnetic field, which was previously—at the process outset—set optimally over the surface of the target. In the case of large changes, this also has a qualitative detrimental effect on the sputtering result. The sputtering process must subsequently be interrupted in order either to readjust the magnet system or to remove unused target material from the process.

It is known that irregularities in the target material, in particular also at high sputtering rates, small deviations in the plasma pattern, i.e. in the qualitative formation of the plasma over the surface of the target, can lead to large variations in the quality of the layers deposited on the substrate.

It is known that shimming occurs at defined distances along the magnet system with small manipulation travel. Here, a maximum manipulation travel perpendicular to the target surface of 1 to 2 mm over all 300 mm length of the magnet system is typical.

Moreover, it is also known that the coating homogeneity can be improved by controlling the process gas; however, different installation situations in the various machines do not lead to comparable results since magnet systems are usually adjusted for a specific sputtering process in specific sputtering surroundings.

WO 96/21750 A1 discloses a magnet arrangement for a cylindrical magnetron, i.e. a magnetron with a tube target, in the interior of which the magnet arrangement is arranged on the magnet support of the magnet system. Proceeding from the prior art, in which a rectangular racetrack is created, i.e. a racetrack with straight-line boundaries, it is proposed therein to arrange magnets obliquely relative to the central axis of the inner magnet section, i.e. relative to the longitudinal extent of the magnet arrangement, in the end region of the racetrack such that these reversal regions are e.g. triangular, parabolic or semi-elliptical.

US 2009/0314631 A1 proposes that at least one additional electromagnetic is arranged between the two magnetic poles of a permanent magnet arrangement in order to influence the shape of the magnetic field lines, wherein the degree of the influence depends on the specific position of the electromagnet in relation to the two pole shoes of the permanent magnet arrangement. Furthermore, it is proposed to provide the permanent magnets with angled surfaces.

The pre-published patent application DE 10 2011 077 297 A1 proposes a magnetron sputtering apparatus comprising a target and a magnet system with an elongate, closed racetrack which comprises three elongate magnetic rods arranged parallel to one another on a coupling plate and two end pieces arranged at the ends of the magnetic rods, which end pieces respectively connect one end of the two outer magnetic rods to one another, wherein target and magnet system can move relative to one another and the magnet system forms a magnetic field penetrating the target for creating an encircling racetrack, and wherein at least one magnet of the magnet system is arranged in the reversal region of the racetrack relative to the normal direction of the surface of the target material such that the magnetic field lines extend asymmetrically relative to the normal direction of the target surface over the surface of the target material in the reversal region of the racetrack such that the region of the target surface in which target material is ablated with a greater intensity than average is displaced with reducing target thickness during the operation of the magnetron sputtering apparatus.

WO 2003/015124 A1 proposes a sputtering magnetron comprising a magnet system associated with a target. The magnet system comprises a magnet arrangement and setting means, wherein the setting means are suitable for deforming or inclining the magnet arrangement, as a result of which it is possible, at least in sections, to modify the distance between the magnet arrangement and the inner face of the target tube.

WO 2009/138348 A1 discloses an option for modifying the position of the magnet system relative to the target surface. To this end, pneumatic, hydraulic or electric adjustment units such as electrical actuators, electromagnetic motors or piezoelectric motors are arranged between the support apparatus of the magnet system and the magnet support. As a result of this, it is possible to vary the distance between the magnet arrangement and the inner face of the target tube during the operation of the sputtering magnetron by means of a cable or tube connection leading out of the sputtering magnetron. By way of example, in this case the distance is set depending on the currently set distance between the magnet system and the inner face of the target tube or the measured magnetic field on the target surface.

An object of the present invention consists of developing a sputtering magnetron for PVD coating of substrates and a method for dynamically influencing the magnetic field during a sputtering process in order to achieve an unchanging and controlled plasma behavior in the case of optimum target material use and also a high coating homogeneity over the service life of the target, wherein the magnetic field is influenced dynamically on the basis of the target material use and the layer quality on the substrate during the running sputtering process, i.e. without ventilating or opening the sputtering installation.

### BRIEF SUMMARY OF THE INVENTION

In order to achieve the object, a sputtering magnetron is proposed for coating a substrate, which comprises a target and a magnet system, wherein target and magnet system can be displaced relative to one another and the magnet system forms a magnetic field that penetrates the target for forming a racetrack, the magnet system further having a support apparatus, a support plate with magnets arranged thereon, and actuators and the support apparatus being connectable to the support plate by means of the actuators such that the distance between the magnet system and the target can be set, at least in sections, the sputtering magnetron further comprising a cooling circuit for cooling the magnet arrangement and the target by means of a coolant, wherein the sputtering magnetron comprises layer measuring means for obtaining data of layer properties of at least one layer deposited on the substrate, and magnet system controls for evaluating the data obtained and for generating manipulated variables, wherein the manipulated variables are the input variables of the actuators.

The proposed device renders it possible to adapt the magnet system to the process in a geometric dynamic fashion, i.e. an adjustment can be undertaken continuously where necessary in order to achieve optimum layer properties. In other words, the form of the magnet system is continuously corrected and updated depending on properties of the deposited layer during the running coating process such that a uniform layer deposition is achieved. In contrast to known solutions, in which the geometric adaptations of the magnet system can only be undertaken during servicing, i.e. outside of the productive process, the proposed device renders it possible to react to changing conditions, e.g. the reducing thickness of the target and the variable magnetic field strength resulting therefrom, while the production process is going on, i.e. during the coating.

In one embodiment of the device, it is proposed to establish a contactless connection between the magnet system controls and the actuators for information interchange. This solution offers a number of advantages: firstly, the cable connections to the actuators which are otherwise required are avoided, as a result of which the device can be produced more cost-effectively. Secondly, the reliability of the device is also increased because the contactless data interchange cannot be impaired by bad contacts or contacts around which coolant may flow.

In a further embodiment of the device, it is proposed that the actuators have at least one common information reception and information transmission unit, and a common control unit. As a result, the complexity due to instruments when implementing the device is significantly reduced compared to a solution in which each actuator has its own information reception and information transmission unit and the device can be produced more cost-effectively.

In a further embodiment of the device, it is proposed that the actuators have at least one common information reception and information transmission unit, and each actuator comprises a separate control unit. This renders it possible to use actuators which already have an integrated control unit when realizing the device.

In a further embodiment of the device, it is proposed that the actuators are surrounded by the coolant from the cooling circuit. The complexity due to instruments is once again significantly reduced compared to a solution in which the actuators have to be shielded with much effort from the coolant.

In a further embodiment of the device, it is proposed that the contactless information interchange is configured by means of modulated sound, modulated light, modulated hydraulic shocks in the coolant or pulsating magnets for actuating reed switches. As a result of the proposed method, reliable signal transmission is also achieved in the interior of the highly energized target, and also through a coolant circulating therein.

In a further embodiment of the device, it is proposed that the contactless means for information interchange can also be employed in combination. By using several different signal-transmission paths, a redundancy is achieved which ensures that the device is extremely robust against external interference and very failsafe and reliable.

In a further embodiment of the device, it is proposed that the actuators are embodied as piezo-ceramic actuators and/or piezoelectric ultrasound motors. These types of actuator are robust and cost-effective.

In a further embodiment of the device, it is proposed that the actuators have a closed energy supply. What this embodiment can achieve is that the actuators operate for long periods of time without additional energy supply.

Furthermore, in order to achieve the stated object, a method is proposed for dynamically influencing the magnetic field during the operation of a sputtering magnetron for coating substrates, the magnet system of which can be displaced relative to the target by means of actuators and the magnet system forms a magnetic field that penetrates the target for forming a racetrack, which method comprises the following method steps:
obtaining data of layer properties of at least one layer deposited on the substrate by layer measuring means during and/or after coating the substrate,
evaluating the obtained data by means of magnet system controls such that it is possible to establish deviations in the layer properties of the layer deposited on the substrate on the basis of a comparison between the obtained data and reference data from a layer with optimum quality and
the magnet system controls generating manipulated variables as input variables of the actuators such that a change in the distance between the magnet system and the target by means of the actuators influences the magnetic field to the extent that the deviations between the obtained data and the reference data are minimized.

The data relating to layer properties used here can, inter alia, comprise the reflectivity, the transmittance, the thickness and further parameters of the deposited layer which can be detected by measurement-technical means.

### BRIEF DESCRIPTION OF THE DRAWING FIGURE

In the following text, the invention will be explained in more detail on the basis of an exemplary embodiment and an associated drawing, wherein the only

FIG. 1 shows an exemplary embodiment of a sputtering magnetron according to the invention.

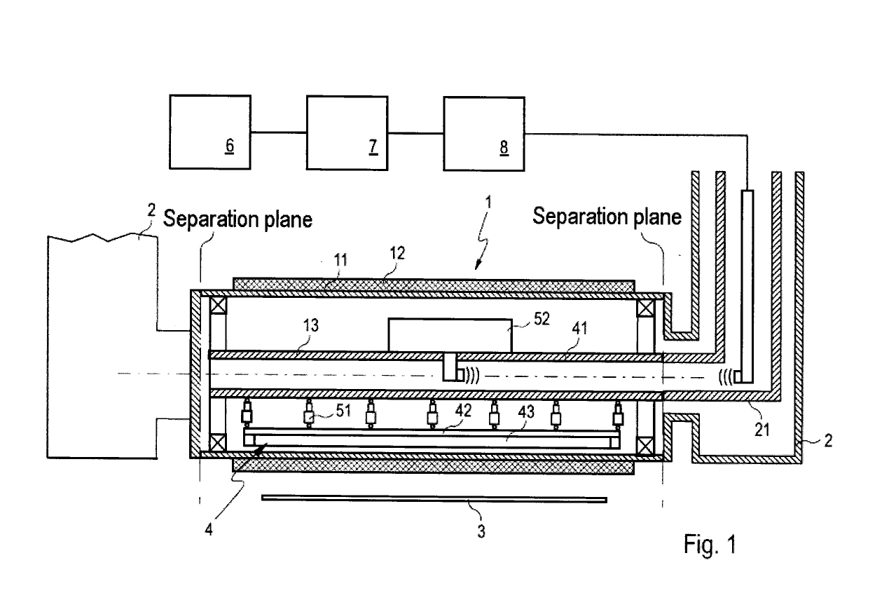

### DETAILED DESCRIPTION

A sputtering magnetron is depicted, which serves to coat substrates with target material 12. A target 1 consists of a target support tube 11 and a target material 12 applied thereto. The target 1 is arranged between two end blocks 2 and rotatably connected to each of the two end blocks 2. The end blocks 2 serve for rotatably driving the target 1 and supplying the target 1 with electricity and coolant. To this end, one of the two end blocks 2 has a coolant feed line 21, which is connected to a lance tube 13 arranged in the interior of the target 1, through which the coolant is routed to the other end of the target 1.

Below the target 1, which is arranged in a coating installation (not depicted here) for coating substrates 3, plate-shaped substrates 3 are moved past the sputtering magnetron, wherein a layer of the target material 12 ablated from the target 1 is deposited on the substrate 3.

The lance tube 13 at the same time serves as support apparatus 41 of a magnet system 4 arranged in the interior of the target 1. An arrangement of several actuators 51 is used to attach a support plate 42 which carries a magnet arrangement 43 to the support apparatus 41. An information transmission and information reception unit 52 is likewise attached to the support apparatus 41 and has a contactless signal connection to the actuators 51. By means of the lance tube 13, i.e. by means of the support apparatus 41 of the magnet system 4, the information transmission and information reception unit 52 establishes a contactless signal connection to magnet system controls 7, which obtain data in relation to the layer properties of the layer deposited on the substrate 3, calculate manipulated variables 8 for the actuators 51 from these data and contactlessly transmit these manipulated variables 8 to the information transmission and information reception unit 52, which transmits the manipulated variables 8 to the actuators 51, likewise in a contactless fashion.

The above-described device renders it possible to achieve an unchanging and controlled plasma behavior whilst having an optimum target material use and a homogeneous coating pattern over the service life of the sputtering target, which can be applied in continuous production processes in particular, more particularly in substrate pass-through installations.

The quality of the coating is optimized and the dynamic manipulation of the magnetic field is rendered possible without ventilating and opening the installation.

It becomes possible to update the magnetic field on the basis of the used-up target material and the dynamic manipulation of the magnetic field on the basis of obtained layer properties on the substrate can be used during the running sputtering process.

Data are obtained during or directly after the substrate coating by means of suitable layer measuring systems, which data are evaluated in magnet system controls and converted into manipulated variables for the manipulation to take place.

Actuators are used to manipulate the magnet system in the established manipulated variables and automatic shimming is carried out during the sputtering process, without ventilating the installation.

1. A sputtering magnetron for coating a substrate, comprising
a target and a magnet system, wherein the target and the magnet system can be displaced relative to one another and the magnet system forms a magnetic field that penetrates the target,
wherein the magnet system has a support apparatus, a support plate with magnets arranged thereon, and actuators, and the support apparatus is connected to the support plate by the actuators such that distance between the magnet system and the target can be set, at least in sections,
a cooling circuit for cooling the magnet system and the target by a coolant,
layer measuring means for obtaining data of layer properties of at least one layer deposited on the substrate, and
magnet system controls for evaluating the data obtained and for generating manipulated variables, wherein the manipulated variables comprise input variables of the actuators.

2. The sputtering magnetron as claimed in claim 1, further comprising a contactless connection between the magnet system controls and the actuators for information interchange.

3. The sputtering magnetron as claimed in claim 2, wherein the actuators have at least one common information reception and information transmission unit, and a common control unit.

4. The sputtering magnetron as claimed in claim 2, wherein the actuators have at least one common information reception and information transmission unit, and each actuator comprises a separate control unit.

5. The sputtering magnetron as claimed in claim 1, wherein the actuators are surrounded by the coolant from the cooling circuit.

6. The sputtering magnetron as claimed in claim 1, wherein the contactless information interchange is implemented by at least one of: modulated sound, modulated light, modulated hydraulic shocks in the coolant, and pulsating magnets for actuating reed switches.

7. The sputtering magnetron as claimed in claim 6, wherein the contactless information interchange is implemented by a combination of at least two of: modulated sound, modulated light, modulated hydraulic shocks in the coolant, and pulsating magnets for actuating reed switches.

8. The sputtering magnetron as claimed in claim 1, wherein the actuators comprise at least one of piezo-ceramic actuators and piezoelectric ultrasound motors.

9. The sputtering magnetron as claimed in claim 1, wherein the actuators have a closed energy supply.

10. A method for dynamically influencing a magnetic field during operation of a sputtering magnetron for coating substrates, the magnetron having a magnet system which can be displaced relative to a target by actuators, and the magnet system forming a magnetic field that penetrates the target, comprising the following steps:
obtaining data of layer properties of at least one layer deposited on a substrate by a layer measuring device during and/or after coating the substrate,
evaluating the obtained data by magnet system controls to establish deviations in layer properties of the layer deposited on the substrate on the basis of a comparison between the obtained data and reference data from a layer with optimum quality, and
the magnet system controls generating manipulated variables as input variables of the actuators such that a change in the distance between the magnet system and the target by the actuators influences the magnetic field to the extent that deviations between the obtained data and the reference data are minimized.
